(19) United States
(12) Patent Application Publication
(10) Pub. No.: US 2026/0037683 A1
(43) Pub. Date: Feb. 5, 2026

(54) DIGITAL TWIN-BASED EQUIPMENT MONITORING SYSTEM FOR MODULAR CLEANROOM

(71) Applicant: LOCUS CELL CO., LTD., New Taipei City (TW)

(72) Inventors: Heng-Yu Liu, New Taipei City (TW); Wei-Ting Lin, New Taipei City (TW); Chih-Wei Cheng, New Taipei City (TW); Hui-Ling Chen, New Taipei City (TW)

(21) Appl. No.: 19/267,696

(22) Filed: Jul. 14, 2025

Related U.S. Application Data
(60) Provisional application No. 63/677,142, filed on Jul. 30, 2024.

(51) Int. Cl. G06F 30/13

(52) U.S. Cl. CPC G06F 30/13

(57) ABSTRACT

A digital twin-based equipment monitoring system for a modular cleanroom, comprising a 3D model construction module, a sensor data processing module, a digital twin module, and a visual display module. The 3D model construction module is configured to establish a 3D model of the modular cleanroom and equipment. The sensor data processing module is configured to detect an operating parameter of the equipment within the modular cleanroom and a consumable usage parameter, thereby generating corresponding equipment status data and consumable replacement data. The digital twin module is configured to perform a simulation calculation based on the equipment status data and consumable replacement data, and utilizes a machine learning model to predict a maintenance schedule and a consumable replacement timing for the equipment to generate corresponding maintenance recommendation data. The visual display module is configured to visualize the aforementioned data, providing a real-time alert and a maintenance recommendation to a user.

The present application is based on, and claims priority from, America provisional patent application number U.S. 63/677,142 filed on 2024 Jul. 30 and the disclosure of which is hereby incorporated by reference herein in its entirety.

### BACKGROUND OF THE INVENTION

### Field of the invention

The present invention relates to a digital twin system, and in particular to a digital twin-based equipment monitoring system for a modular cleanroom.

### Description of the prior art

In modern biopharmaceutical and cell therapy industries, cell culture processes demand extremely high requirements for sterile environment and standardized operation. Cell factories typically utilize cleanrooms to control contamination risks and ensure that the culturing processes comply with strict production regulations. However, existing cleanroom systems still face various challenges in cell culture and equipment monitoring, including the following:
1. Difficulty in equipment maintenance and consumable replacement management
   In traditional cleanrooms, cell culture equipment (such as incubators, biosafety cabinets, and centrifuges) relies on manual inspection to monitor operating conditions and consumable usage. Due to the long duration of cell culture cycles, the changes in the operating status of the equipment may occur during inspection intervals, making it difficult to detect failures or shortages of consumables in time, thereby affecting production progress and culture quality.
2. Manual dependence for sterile environment monitoring
   Current technologies often rely on periodic sampling to monitor air quality (e.g., airborne particles and microbial contamination) inside the cleanrooms. However, such methods do not reflect environmental changes in real time, and the sampling process itself may increase contamination risks. Moreover, personnels' entering and exiting cleanroom are a potential source of contamination, and the lack of real-time monitoring mechanisms makes contamination difficult to control promptly.
3. Lack of digital twin monitoring for equipment consumable usage
   The usage status of consumables (such as culture dishes, pipettes, media, and filters) in cell culture equipment is still recorded manually or replaced on a fixed schedule, resulting in inaccurate replacement timing, potential waste, or culture disruption due to exhausted consumables. Furthermore, current systems are unable to track or optimize internal equipment parameters (such as CO₂ concentration, temperature, and humidity) and consumable consumption in real time.
4. Poor management of equipment anomalies and maintenance scheduling
   When equipment anomalies occur during the cell culture process (e.g., abnormal incubator temperature, CO₂ imbalance, and media pH fluctuations), diagnosis and repair often rely on manual intervention, causing production delays or batch failure. In addition, existing maintenance models are mostly scheduled maintenance, lacking real-time adjustment based on actual equipment usage, which may lead to over-maintenance or insufficient response to failures.
5. Insufficient standardization and data integration in the cell culture process
   While equipment in traditional cell factories may have monitoring functions, most of them lack data integration across devices. As a result, critical parameters (such as cell growth curves, media composition changes, and operational data) cannot be analyzed or optimized in real time. Furthermore, inconsistencies in the operators' skills and experiences may lead to variability in the culture outcomes, increasing risks in product quality and production consistency.

To address the above-mentioned problems, recent technologies have begun applying digital twin technology to cleanroom monitoring and equipment management for real-time data tracking and intelligent decision-making. Nevertheless, current technologies still exhibit the following limitations:
1. Limited scope of digital twin applications
   Existing systems are primarily focused on monitoring production equipment status, and are rarely integrated with cell culture equipment and consumable management. This perpetuates reliance on manual intervention for equipment monitoring and consumable replacement, preventing truly autonomous operation.
2. Inadequate equipment anomaly prediction and maintenance optimization
   Most current systems rely on simple threshold alarms (for example, triggering only when incubator temperature exceeds a preset range) and do not use historical data or machine learning models to predict anomaly detection. Consequently, many equipment issues remain undetected until failure, compromising production stability.
3. Lack of integration between consumable replacement mechanisms and equipment monitoring systems
   In conventional systems, consumables are replaced based on fixed schedules or manual judgment rather than dynamic adjustment based on actual usage. This may result in premature replacement of consumables, thereby increasing costs, or in delayed replacement, which could adversely affect the outcomes of cell culture. Moreover, existing systems lack integration with supply chain management, preventing automatic restocking when inventory runs low and impacting production plans.
4. Limited data integration for cleanroom environment monitoring
   Although existing systems monitor cleanroom air quality and environmental parameters, such data are often stored across separated platforms without unified analysis or decision-making frameworks. It is thus difficult for production managers to gain comprehensive insights in real-time, impeding contamination control and equipment management.
5. Manual operations remaining a critical factor affecting production efficiency and quality
   Current digital twin technologies are primarily used for passive monitoring and are not deeply integrated with robotic arms or automation equipment to replace manual cell culture operations (e.g., seeding, media exchange, subculturing, and harvesting). As a result, cell factories still rely on human operators, which increases the risk of human errors and affects production efficiency and standardization.

Therefore, it is necessary to design a digital twin system for modular cleanrooms, which can monitor the equipment in such environments and thereby resolve the aforementioned problems.

### SUMMARY OF THE INVENTION

In view of this, the present invention provides a digital twin-based equipment monitoring system for a modular cleanroom, so as to address the aforementioned conventional problems.

The present invention provides a digital twin-based equipment monitoring system for a modular cleanroom. The system comprises a 3D model construction module, a sensor data processing module, a digital twin module and a visual display module. The 3D model construction module is configured to construct a modular cleanroom and a 3D model of an equipment. Wherein, the modular cleanroom comprises a cleanroom comprising a plurality of partition panels. The sensor data processing module is coupled to the 3D model construction module. The sensor data processing module is configured to sense an operating parameter of the equipment and a consumable usage parameter, so as to generate corresponding an equipment status data and a consumable replacement data. The digital twin module is coupled to the 3D model construction module and the sensor data processing module. The digital twin module is configured to perform a simulation calculation based on the equipment status data and the consumable replacement data, and to generate a maintenance recommendation data by predicting a maintenance schedule and a consumable replacement timing for the equipment using a machine learning model. The visual display module is coupled to the digital twin module. The visual display module is configured to visualize the equipment status data, the consumable replacement data, and the maintenance recommendation data, so as to provide a user with a real-time alert and a maintenance recommendation.

Wherein, the sensor data processing module further comprises at least one sensing device disposed on each of the partition panels and the equipment. The at least one sensing device is configured to detect the operating parameter and the consumable usage parameter of the equipment in real time, to generate a sensor data according to the operating parameter and the consumable usage parameter, and to transmit the sensor data to the digital twin module.

Wherein, the digital twin module further comprises a data computation and analysis unit. The data computation and analysis unit is configured to predict an optimal maintenance cycle and an optimal consumable replacement time for the equipment based on the equipment status data and the consumable replacement data via the machine learning model, and to provide an equipment operation optimization suggestion.

Wherein, the visual display module further comprises a mobile device. The mobile device comprises one of a smartphone, a computer, or a tablet. The mobile device is configured to receive the maintenance recommendation data via a wireless communication, and to provide the user with a real-time control and a remote monitoring.

Wherein, the digital twin module is further configured to perform a historical data analysis on the equipment status data to establish an equipment operation failure model, and to provide an equipment maintenance and replacement strategy recommendation based on the equipment operation failure model.

Wherein, the equipment comprises one or more of the following: a cell incubator, a cell sterile operation table, a conveyor belt, a turntable, and a robotic arm.

Wherein, the digital twin-based equipment monitoring system for the modular cleanroom is applied to a cell factory. The modular cleanroom further comprises a plurality of cleanrooms. Each of the cleanrooms comprises a plurality of partition panels. Each of the partition panels is configured for rapid assembly to form an interior space and an exterior region. The cell factory operates under a contract development and manufacturing organization (CDMO) model. Each of the partition panels is a movable partition panel. The interior space of each of the cleanrooms is an airtight space maintained under positive pressure and laminar flow to achieve a predetermined cleanliness level.

Wherein, when the cell factory schedules a yearly maintenance or a production schedule, the cleanroom that is designated from the modular cleanrooms is reconfigured by quickly disassembling each of the movable partition panels based on the yearly maintenance or the production schedule, so as to accommodate the yearly maintenance or the production schedule.

Wherein, the digital twin-based equipment monitoring system for the modular cleanroom further comprises a pre-warning module. The pre-warning module is coupled to the digital twin module and the visual display module. When the pre-warning module receives the equipment status data indicating a potential failure or when the consumable replacement data reaches a preset threshold, the pre-warning module is configured to transmit the real-time alert to the user via the visual display module and to provide maintenance recommendations.

Wherein, the consumable replacement data of the equipment further comprises a consumable lifetime, a real-time consumption rate, and a replacement cycle information, and the digital twin module is configured to establish an optimal replacement schedule based thereon.

Compared with the prior art, the digital twin-based equipment monitoring system for a modular cleanroom of the present invention is capable of creating a virtual cell culture environment using digital twin technology, thereby enabling real-time simulation and monitoring of equipment operation conditions across multiple cleanrooms. Furthermore, by incorporating a machine learning model, the system can predict equipment anomalies and optimize maintenance schedules based on actual equipment operation data, thereby extending equipment lifespan and reducing the risk of production interruption. In addition, the system of the present invention integrates AI-driven robotic arm simulation and learning capabilities to analyze the impact of robotic arm operations on cell culture outcomes, ensuring standardization and stability in the culturing process. It further optimizes mechanical gripping force, motion trajectories, and liquid exchange modes through data analysis, thereby minimizing the risk of cell damage. The system of the present invention also consolidates data related to equipment status, culture parameters, and consumable replacement, ensuring real-time monitoring of all critical equipment and production processes within the cell factory. Through comprehensive data analysis, the system enables operational strategy optimization, thereby reducing contamination and resource waste. Moreover, by using sensing devices to monitor environmental parameters of the cleanroom in real time (such as temperature, humidity, airflow, vibration, and gas concentration), the system achieves dynamic environmental control to ensure stable production conditions. The system of the present invention further establishes a risk assessment and contamination control mechanism across multiple cleanrooms by simulating the movements and interactions of robotic arms and equipment in different cleanrooms via the digital twin-based equipment monitoring system, thereby preventing cross-contamination. By accumulating and analyzing operational data, the system of the present invention can propose optimal cleanroom configurations and contamination control strategies to reduce production risks and enhance operational efficiency. In addition, by integrating AR/VR-based remote monitoring and real-time adjustment functions, the system of the present invention enhances automation within the cell factory, allowing operators to remotely monitor equipment status and adjust operating parameters in real time, thereby reducing the need for personnels to enter/exit cleanrooms, effectively lowering contamination risk, and improving production efficiency and operational stability. In summary, the digital twin-based equipment monitoring system for the modular cleanroom of the present invention can comprehensively optimize the operational model of a cell factory, improve equipment management efficiency, ensure the production environment to meet high cleanliness standards, and promote the development of intelligent and automated cell culture technologies.

### BRIEF DESCRIPTION OF THE APPENDED DRAWINGS

Some of the embodiments will be described in detail, with reference to the following figures, wherein like designations denote like members, wherein:

FIG. 1 shows a functional block diagram of a digital twin-based equipment monitoring system for a modular cleanroom of one embodiment of the present invention.

FIG. 2 shows a functional block diagram of a digital twin-based equipment monitoring system for a modular cleanroom of another embodiment of the present invention.

FIG. 3 shows a functional block diagram of a digital twin-based equipment monitoring system for a modular cleanroom of another embodiment of the present invention.

FIG. 4 shows a functional block diagram of a digital twin-based equipment monitoring system for a modular cleanroom of another embodiment of the present invention.

### DETAILED DESCRIPTION OF THE INVENTION

In order to make the advantages, spirit and features of the present invention easier and clearer, it will be detailed and discussed in the following with reference to the embodiments and the accompanying drawings. It is worth noting that the specific embodiments are merely representatives of the embodiments of the present invention. The specific methods, devices, conditions, and materials described herein are not intended to limit the scope of the invention or the embodiments corresponding thereto. Additionally, the components illustrated in the drawings are intended only to indicate relative positions and are not necessarily drawn to scale. The step numbers used in the present invention are for distinguishing between steps only and do not imply any particular execution order unless otherwise stated.

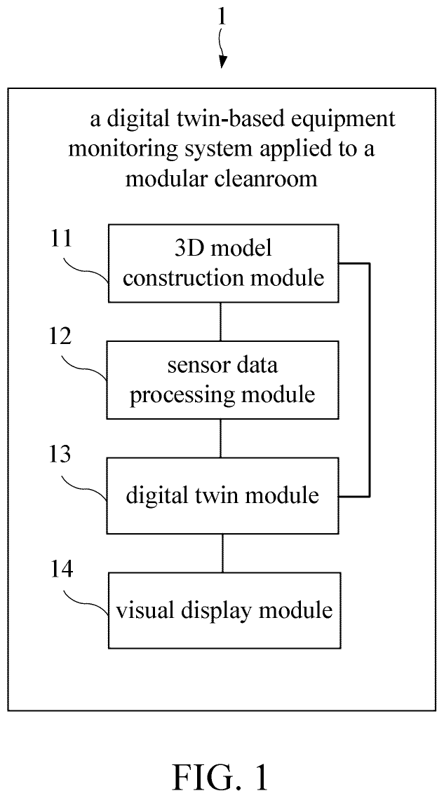

Please refer to FIG. 1, FIG. 1 shows a functional block diagram of a digital twin-based equipment monitoring system 1 for a modular cleanroom of one embodiment of the present invention. In this embodiment, the digital twin-based equipment monitoring system 1 comprises a 3D model construction module 11, a sensor data processing module 12, a digital twin module 13, and a visual display module 14.

In this embodiment, the 3D model construction module 11 is configured to establish a three-dimensional model of the modular cleanroom (not shown in the figure) and equipment (also not shown). The modular cleanroom in this embodiment may include a cleanroom (not shown), which comprises a plurality of partition panels that are configured for rapid assembly to form an interior space and an exterior region. The equipment in this embodiment may be installed within the interior space. The equipment may further include one or more of the following: a cell incubator, a cell sterile operating table, a conveyor belt, a turntable, and a robotic arm. The robotic arm may be configured to simulate human operations involved in cell culture processes (e.g., seeding, medium exchange, subculturing, and sampling), and may be precisely monitored and subjected to motion optimization through digital twin technology. However, in practice, the types of equipment are not limited to the examples mentioned above and may be selected and configured based on users' requirements and the instruments needed for the production process.

In this embodiment, the sensor data processing module 12 is coupled to the 3D model construction module 11 and is configured to sense operating parameters and consumable usage parameters of the equipment in the modular cleanroom, so as to generate corresponding equipment status data and consumable replacement data. In this embodiment, the operating parameters may further comprise ambient temperature, equipment temperature, ambient humidity, airflow variations, vibration frequency, and the like. The consumable usage parameters may comprise consumption volume of culture media, replacement frequency of filter membranes, and the like. In addition, in practical applications involving the monitoring of robotic arms, the sensor data processing module 12 may also record, in real time, the motion trajectories, gripping force, movement speed, and operational accuracy of the robotic arm, so as to ensure that its actions conform to standardized procedures and to reduce the risk of operational errors.

In addition, the digital twin module 13 in this specific embodiment is coupled to the 3D model construction module 11 and the sensor data processing module 12. The digital twin module 13 is configured to perform simulation computations based on the equipment status data and the consumable replacement data, and to generate maintenance recommendation data by predicting the maintenance schedule for the equipment and the timing for consumable replacement using a machine learning model. In this embodiment, for robotic arms, the digital twin module 13 may also simulate the operational performance of the robotic arm under different environmental conditions, such as varying airflow states or temperature and humidity levels, to evaluate their impacts and perform optimization settings, thereby ensuring motion stability and reproducibility in the cell culture process. The visual display module 14 is coupled to the digital twin module 13 and is configured to visually present the equipment status data, the consumable replacement data, and the maintenance recommendation data, so as to provide the user with real-time alerts and maintenance suggestions. In practical implementation, the 3D model construction module 11, the sensor data processing module 12, the digital twin module 13, and the visual display module 14 of the digital twin-based equipment monitoring system 1 for a modular cleanroom may be integrated into a computer system, a cloud-based central processing unit, or a system-on-chip (SoC).

In one embodiment, when the digital twin-based equipment monitoring system 1 for a modular cleanroom is used to monitor a robotic arm performing cell culture operations, it may utilize digital twin technology and artificial intelligence (AI) machine learning to monitor equipment status. This enables the robotic arm to reduce contamination risks and operational errors associated with manual operations. Moreover, by analyzing equipment operation data and airflow dynamics, the system can proactively predict sensitive areas that may be affected, thereby preventing disturbances or damage to the cell culture process caused by airflow at the source. This aspect is particularly critical, as cell culture requires highly precise and stable operations. If the environment is disturbed by vibration or airflow fluctuations, the rate of cell division may significantly decrease, resulting in large variations in data and impacting culture outcomes. In this embodiment, the digital twin module 13 may also simulate airflow dynamics within the cleanroom to assess the contamination risk caused by the movement of the robotic arm, and provide optimal operational recommendations accordingly. Furthermore, through data accumulation and algorithm optimization, the digital twin module 13 can progressively enhance the standardization of the culture process, ensure the operational stability of the robotic arm, and improve the consistency and reproducibility of the production workflow.

In practical applications, the digital twin-based equipment monitoring system 1 in this embodiment for a modular cleanroom may be used in a high-cleanliness environment. The high-cleanliness environment may further include a biopharmaceutical factory, a dust-free production line, and a cell factory, for the purpose of monitoring equipment operating parameters and ensuring the operational stability of the equipment. When the digital twin-based equipment monitoring system 1 is applied to a cell factory, the modular cleanroom may further comprise a plurality of cleanrooms. Each cleanroom comprises a plurality of partition panels, which are configured for rapid assembly to form an interior space and an exterior region. In addition, the cell factory may operate under a contract development and manufacturing organization (CDMO) model. Each of the partition panels is a movable partition panel, and the material of the partition panels may include stainless steel, aluminum alloy, high-pressure laminate (HPL), or other composite materials. Each partition panel may be rapidly installed or removed using joining components, such as sealing strips, snap-fit joints, or clamping fasteners, to allow easy assembly and disassembly between panels. The interior space of each cleanroom is an airtight space, which maintains positive pressure and laminar airflow, thereby allowing the cleanroom to meet a predetermined cleanliness level. The predetermined cleanliness level may be Class 4, which corresponds to ISO 8 standards. In practice, the material of the partition panels and the type of joining components are not limited to the examples described herein, and may be adjusted and designed according to users' requirements, production needs, or specific technical specifications.

Since modular cleanrooms can be assembled using movable partition panels, the utilization efficiency of space within a cell factory can be significantly improved. The modular cleanroom can be rapidly and flexibly configured based on production requirements to allocate the required spaces for various schedules, wherein multiple internal areas are assembled using the plurality of partition panels, thereby enhancing the overall flexibility and production efficiency of the cell factory. In addition, with respect to the operational environment of robotic arms, digital twin simulation technology may be employed to monitor, in real time, the performance of the robotic arm under different environmental parameters, ensuring its motion precision and stability under various cleanroom conditions. Furthermore, in this embodiment, the partition panels featuring quick assembly and disassembly enable each cleanroom to function as an independent and isolated space. Accordingly, when the digital twin-based equipment monitoring system for the modular cleanroom as provided in the present invention implemented in a CDMO cell factory allows for the adjustment of the number of cleanrooms or the relocation of cleanrooms to different positions based on the duration or condition of the scheduled yearly maintenance of equipment, thereby accommodating maintenance or production scheduling even when equipment maintenance is required within the cell factory. Additionally, based on the independence of the equipment in each cleanroom and staggered maintenance needs, when the cell factory arranges a yearly maintenance or production schedule, specific cleanrooms may be detached and reconfigured through rapid disassembly of the movable partition panels, so as to meet the requirements of such yearly maintenance or production schedule.

In this embodiment, the digital twin-based equipment monitoring system 1 for the modular cleanroom can incorporate various machine learning models to enhance the accuracy and automation level of equipment monitoring, fault prediction, maintenance optimization, and contamination risk control within the modular cleanroom. Specifically, equipment fault detection and prediction models (e.g., LSTM, Random Forest) can identify potential failures in advance based on operational data, thereby preventing unplanned downtime. Optimal maintenance scheduling models (e.g., reinforcement learning and Bayesian networks) dynamically adjust the maintenance cycles in real time, extending equipment lifespan. For robotic arm motion control, the system of this embodiment adopts deep reinforcement learning and convolutional neural network (CNN) models to optimize gripping force and motion trajectory, thereby reducing shear stress during the cell culture process. Additionally, through environmental control and contamination risk assessment models (e.g., decision trees and graph neural networks), the system can monitor airflow, temperature, humidity, and particle concentration in the cleanroom in real time, predict contamination risks, and adjust operational strategies to avoid cross-contamination. In terms of consumable management and supply chain optimization, the system uses LSTM and XGBoost models to predict the replacement timing of consumables such as culture media and filtration membranes, ensuring supply chain stability. Finally, by integrating digital twin simulations with operation optimization models (e.g., GANs and simulation-enhanced learning), the system of this embodiment can forecast optimal production processes, further improving the operational efficiency and production stability of equipment within the cleanroom, thereby ensuring high-standard execution of cell culture and biopharmaceutical processes. In practice, the types and configurations of machine learning models are not limited thereto and may be selected or combined based on the specific application scenario and characteristics of the data, in order to achieve more accurate equipment monitoring, maintenance management, and production optimization outcomes.

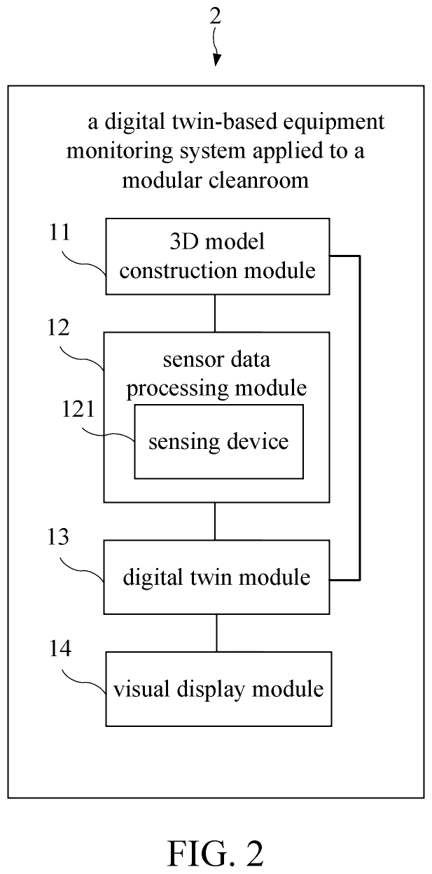

Please refer to FIG. 2, FIG. 2 shows a functional block diagram of a digital twin-based equipment monitoring system 2 for a modular cleanroom of another embodiment of the present invention. The difference between this embodiment and the aforementioned embodiment lies in that the sensing data processing module 12 in this embodiment further comprises at least one sensing device 121. The sensing device 121 is disposed on the partition panels, equipment bodies, airflow ducts, and critical areas of the cleanroom, and is configured to detect the operating parameters of the equipment and the consumable usage parameters in real time. The sensing device 121 generates sensing data based on the operating parameters and the consumable usage parameters and transmits the sensing data to the digital twin module 13. In practice, the installation position of the sensing device 121 is not limited to the examples mentioned above and may be flexibly adjusted and optimally configured according to the parameters to be monitored, the operating characteristics of the equipment, environmental conditions, and measurement requirements. The sensing device 121 in this embodiment may include, but is not limited to, the following types:
1. Temperature and humidity sensors: to monitor environmental temperature and humidity inside and outside the equipment, ensuring stability of the cell culture environment.
2. Airflow sensors: to detect the speed and direction of airflow within the cleanroom, maintaining optimal sterile conditions.
3. Vibration and pressure sensors: to monitor vibrations and stress variations during robotic arm operation in real time, ensuring stability in cell handling processes.
4. Imaging and optical sensors: using high-resolution cameras and optical sensing technologies to monitor the state of cell cultures, equipment operation status, and abnormal variations.
5. Gas and contaminant sensors: to monitor CO₂, O₂ concentrations and airborne particle counts in the cleanroom, ensuring environmental quality complied with bioprocessing standards.
6. RFID and barcode scanning sensors: to track the usage history of consumables and equipment, ensuring accurate replacement cycles and optimizing logistics management.

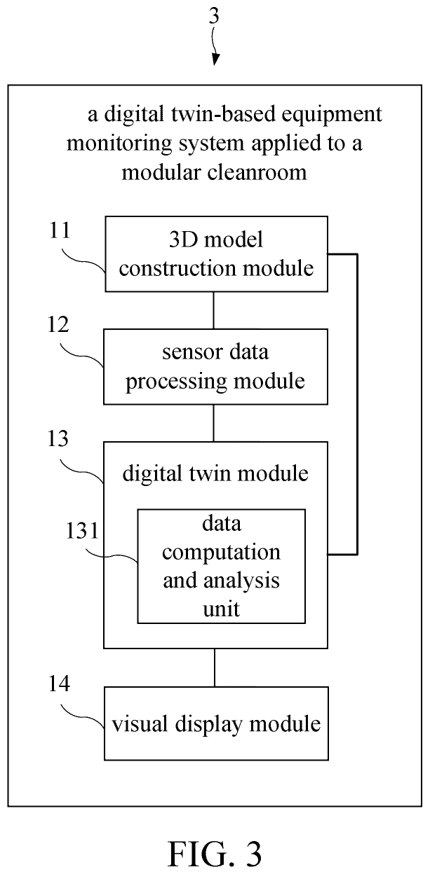

The sensing data generated by the sensing device 121 is transmitted in real time to the digital twin module 13 for subsequent analysis and optimization of equipment operation strategies. This approach not only enhances the stability of the cell culture process but also reduces the need for manual monitoring through data-driven methods, thereby lowering production risks. It should be noted that other modules, models, and their corresponding functions in the digital twin-based equipment monitoring system 2 for modular cleanrooms in this embodiment are generally the same as those in the aforementioned embodiments and will not be redundantly described herein. Please refer to FIG. 3, FIG. 3 shows a functional block diagram of a digital twin-based equipment monitoring system 3 for a modular cleanroom of another embodiment of the present invention. In this embodiment, the digital twin module 13 of the digital twin-based equipment monitoring system 3 further comprises a data computation and analysis unit 131. The data computation and analysis unit 131 is configured to, based on the equipment status data and consumable replacement data, predict the optimal equipment maintenance cycle and optimal consumable replacement timing using machine learning models, and to provide optimization recommendations for equipment operation. In practice, the digital twin-based equipment monitoring system 3 of this embodiment can dynamically analyze and optimize the operation of robotic arms. Through AI technologies, the digital twin-based equipment monitoring system 3 adjusts their operation strategies, for example, optimizing gripping force, motion trajectory, and liquid exchange patterns via AI analysis to ensure low shear force impacts during cell culture operations, thereby reducing the likelihood of cell damage. Furthermore, the system of this embodiment can also detect real-time variations in temperature, vibration frequency, and operational precision of the robotic arm to ensure long-term operational stability and to predict potential anomalies early, thereby avoiding deviations that may affect culture outcomes. It should be noted that other modules, models, and their corresponding functions in the digital twin-based equipment monitoring system 3 for modular cleanrooms in this embodiment are generally the same as those in the aforementioned embodiments and will not be redundantly described herein.

In another embodiment, the digital twin module 13 is further configured to perform historical data analysis on the equipment status data to establish an equipment failure model and, based on the failure model, provide recommendations for equipment maintenance and replacement strategies. The consumable replacement data of the equipment further includes consumable lifetime, real-time consumption rate, and replacement cycle information, and the optimal replacement schedule is established by the digital twin module to reduce unplanned equipment downtime. Moreover, the system of this embodiment may also utilize the accumulated data to build predictive models, thereby further optimizing equipment lifespan and maintenance strategies to ensure long-term stable operation and to reduce the risk of unexpected failures.

In another embodiment, the visual display module 14 further includes a mobile device. The mobile device may further comprise a smartphone, a computer, or a tablet, and is configured to receive maintenance recommendation data via wireless communication and provide the user with real-time control and remote monitoring capabilities. In practical applications, the visual display module 14 may also include a multi-device monitoring interface and support AR/VR-based remote monitoring functions, which are used to display the real-time status of all equipment inside the cleanroom, including incubators, biosafety cabinets, and robotic arms. Furthermore, with the use of AR/VR technology, the system can offer remote monitoring and operational simulation, enabling operators to adjust equipment parameters in real time, thereby reducing the need for the personnel to enter the cleanroom and further lowering the risk of cross-contamination. In this embodiment, data synchronization among the three-dimensional model construction module 11, the perception data processing module 12, the digital twin module 13, and the visual display module 14 may be carried out via wireless communication (e.g., Wi-Fi, Zigbee or 5G) or wired communication (e.g., Ethernet or RS-485), to provide real-time operational monitoring and ensure the accuracy and timeliness of equipment data.

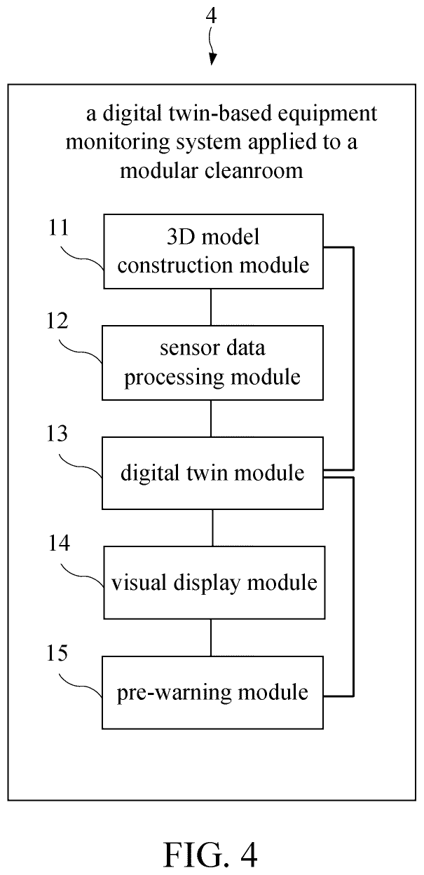

Please refer to FIG. 4, FIG. 4 shows a functional block diagram of a digital twin-based equipment monitoring system 4 for a modular cleanroom of another embodiment of the present invention. In this embodiment, the digital twin-based equipment monitoring system 4 for a modular cleanroom further includes a warning module 15. The warning module 15 is coupled to the digital twin module 13 and the visual display module 14 to monitor the operational status of equipment in real time and provide alerts and maintenance recommendations when necessary. When the warning module 15 receives equipment status data indicating that a malfunction may occur (e.g., excessive temperature, abnormal airflow, abnormal vibration, or abnormal consumable usage), or when the consumable replacement data reaches a predefined threshold, the system can send immediate alerts and maintenance suggestions to the user through the visual display module 14. In addition, the warning module 15 may also transmit notifications to a mobile device (such as a smartphone, tablet, or computer), allowing operators to perform remote adjustments to ensure the stability and continuity of equipment operation.

Furthermore, the system of the present invention can correspond to the actual production line process of a cell factory. Through continuous data monitoring, the system can actively identify, detect, or discover abnormalities or deviations. Built-in data analysis and machine learning algorithms are used to classify and assess such anomalies. When an abnormal condition is detected, the warning module 15 can issue a real-time alert and provide diagnostic information, such as the potential cause of the anomaly, the affected scope, and recommended solutions, thereby assisting operators in follow-up control and decision-making. For example, during the cell cultivation process, when the robotic arm performs media replacement, its operational parameters (including gripping force, movement trajectory, and shear force effect) are monitored. If a media replacement anomaly or uneven media exchange is detected, the system will immediately issue a notification and suggest adjusting the robotic arm parameters or performing equipment calibration to ensure process stability. The application of this technology not only enhances the operational stability within the cleanroom, but also enables the establishment of accurate predictive models through data analysis, thereby optimizing equipment maintenance cycles, reducing unplanned downtime, and minimizing production risks. It should be noted that the other modules, models, and corresponding functions of the digital twin-based equipment monitoring system 4 for the modular cleanroom in this embodiment are substantially the same as those described in the aforementioned embodiments and will not be redundantly described herein.

Compared with the prior art, the digital twin-based equipment monitoring system for a modular cleanroom of the present invention is capable of creating a virtual cell culture environment using digital twin technology, thereby enabling real-time simulation and monitoring of equipment operation conditions across multiple cleanrooms. Furthermore, by incorporating a machine learning model, the system can predict equipment anomalies and optimize maintenance schedules based on actual equipment operation data, thereby extending equipment lifespan and reducing the risk of production interruption. In addition, the system of the present invention integrates AI-driven robotic arm simulation and learning capabilities to analyze the impact of robotic arm operations on cell culture outcomes, ensuring standardization and stability in the culturing process. It further optimizes mechanical gripping force, motion trajectories, and liquid exchange modes through data analysis, thereby minimizing the risk of cell damage. The system of the present invention also consolidates data related to equipment status, culture parameters, and consumable replacement, ensuring real-time monitoring of all critical equipment and production processes within the cell factory. Through comprehensive data analysis, the system enables operational strategy optimization, reducing contamination and resource waste. Moreover, by using sensing devices to monitor environmental parameters of the cleanroom in real time (such as temperature, humidity, airflow, vibration, and gas concentration), the system achieves dynamic environmental control to ensure stable production conditions. The system of the present invention further establishes a risk assessment and contamination control mechanism across multiple cleanrooms by simulating the movements and interactions of robotic arms and equipment in different cleanrooms via the digital twin-based equipment monitoring system, thereby preventing cross-contamination. By accumulating and analyzing operational data, the system of the present invention can propose optimal cleanroom configurations and contamination control strategies to reduce production risks and enhance operational efficiency. In addition, by integrating AR/VR-based remote monitoring and real-time adjustment functions, the system of the present invention enhances automation within the cell factory, allowing operators to remotely monitor equipment status and adjust operating parameters in real time, thereby reducing the need for personnels to enter/exit cleanrooms, effectively lowering contamination risk, and improving production efficiency and operational stability. In summary, the digital twin-based equipment monitoring system for the modular cleanroom of the present invention can comprehensively optimize the operational model of the cell factory, improve equipment management efficiency, ensure the production environment to meet high cleanliness standards, and promote the development of intelligent and automated cell culture technologies.

With the detailed description of the above embodiments, it is hoped that the features and spirit of the present invention can be more clearly described, and the scoped of the present invention is not limited by the embodiments disclosed above. On the contrary, the intention is to cover various changes and equivalent arrangements within the scope of the patents to be applied for in the present invention. Therefore, the scope of the patent application for the present invention should be interpreted broadly based on the above description so as to cover all possible changes and equivalent arrangements.

What is claimed is:

1. A digital twin-based equipment monitoring system for a modular cleanroom, the system comprising:
a 3D model construction module configured to construct a modular cleanroom and a 3D model of an equipment, wherein the modular cleanroom comprises a cleanroom comprising a plurality of partition panels;
a sensor data processing module coupled to the 3D model construction module, the sensor data processing module configured to sense an operating parameter of the equipment and a consumable usage parameter, so as to generate corresponding an equipment status data and a consumable replacement data;
a digital twin module coupled to the 3D model construction module and the sensor data processing module, the digital twin module configured to perform a simulation calculation based on the equipment status data and the consumable replacement data, and to generate a maintenance recommendation data by predicting a maintenance schedule and a consumable replacement timing for the equipment using a machine learning model; and
a visual display module coupled to the digital twin module, the visual display module configured to visualize the equipment status data, the consumable replacement data, and the maintenance recommendation data, so as to provide a user with a real-time alert and a maintenance recommendation.

2. The digital twin-based equipment monitoring system for the modular cleanroom of claim 1, wherein the sensor data processing module further comprises:
at least one sensing device disposed on each of the partition panels and the equipment, the at least one sensing device configured to detect the operating parameter and the consumable usage parameter of the equipment in real time, to generate a sensor data according to the operating parameter and the consumable usage parameter, and to transmit the sensor data to the digital twin module.

3. The digital twin-based equipment monitoring system for the modular cleanroom of claim 1, wherein the digital twin module further comprises:
a data computation and analysis unit configured to predict an optimal maintenance cycle and an optimal consumable replacement time for the equipment based on the equipment status data and the consumable replacement data via the machine learning model, and to provide an equipment operation optimization suggestion.

4. The digital twin-based equipment monitoring system for the modular cleanroom of claim 1, wherein the visual display module further comprises:
a mobile device comprising one of a smartphone, a computer, or a tablet, and the mobile device configured to receive the maintenance recommendation data via a wireless communication, and to provide the user with a real-time control and a remote monitoring.

5. The digital twin-based equipment monitoring system for the modular cleanroom of claim 1, wherein the digital twin module is further configured to perform a historical data analysis on the equipment status data to establish an equipment operation failure model, and to provide an equipment maintenance and replacement strategy recommendation based on the equipment operation failure model.

6. The digital twin-based equipment monitoring system for the modular cleanroom of claim 1, wherein the equipment comprises one or more of the following: a cell incubator, a cell sterile operation table, a conveyor belt, a turntable, and a robotic arm.

7. The digital twin-based equipment monitoring system for the modular cleanroom of claim 1, wherein the digital twin-based equipment monitoring system for the modular cleanroom is applied to a cell factory, and the modular cleanroom further comprises a plurality of cleanrooms, each of the cleanrooms comprises a plurality of partition panels, each of the partition panels is configured for rapid assembly to form an interior space and an exterior region, and the cell factory operates under a contract development and manufacturing organization (CDMO) model, each of the partition panels is a movable partition panel, and the interior space of each of the cleanrooms is an airtight space maintained under positive pressure and laminar flow to achieve a predetermined cleanliness level.

8. The digital twin-based equipment monitoring system for the modular cleanroom of claim 7, wherein when the cell factory schedules a yearly maintenance or a production schedule, the cleanroom that is designated from the modular cleanrooms is reconfigured by quickly disassembling each of the movable partition panels based on the yearly maintenance or the production schedule, so as to accommodate the yearly maintenance or the production schedule.

9. The digital twin-based equipment monitoring system for the modular cleanroom of claim 1, further comprising:
a pre-warning module coupled to the digital twin module and the visual display module, wherein when the pre-warning module receives the equipment status data indicating a potential failure or when the consumable replacement data reaches a preset threshold, the pre-warning module is configured to transmit the real-time alert to the user via the visual display module and to provide maintenance recommendations.

10. The digital twin-based equipment monitoring system for the modular cleanroom of claim 1, wherein the consumable replacement data of the equipment further comprises a consumable lifetime, a real-time consumption rate, and a replacement cycle information, and the digital twin module is configured to establish an optimal replacement schedule based thereon.
